(19) United States
(12) Patent Application Publication
(10) Pub. No.: US 2011/0094582 A1
(43) Pub. Date: Apr. 28, 2011

(54) PHOTOCHEMICAL ELECTRODE, CONSTRUCTION AND USES THEREOF

(75) Inventors: Itamar Willner, Mevasseret Zion (IL); Ran Tel-Vered, Jerusalem (IL); Huseyin Bekir Yildiz, Antalya (TR)

(73) Assignee: Yissum Research Development Company of the Hebrew University of Jerusalem, Ltd., Jerusalem (IL)

(21) Appl. No.: 12/994,821

(22) PCT Filed: Jun. 28, 2009
(86) PCT No.: PCT/IL09/00641

§ 371 Date: Jan. 10, 2011

Related U.S. Application Data
(60) Provisional application No. 61/075,947, filed on Jun. 26, 2008.

(51) Int. Cl. H01L 31/0352; H01L 29/15; H01L 21/20; B82Y 99/00

(52) U.S. Cl. 136/256; 257/22; 438/478; 257/21; 977/773; 257/E29.075; 257/E21.09; 257/E31.033

(57) ABSTRACT

Provided is an electrode including a conductive surface connected to a matrix; the matrix including a plurality of semiconductor nanoparticles and noble metal nanoparticles, substantially each of which is connected to another nanoparticle of the plurality of nanoparticles by at least one matrix connecting group and at least a portion of the plurality of nanoparticles of the matrix is each connected to the conductive surface by at least one surface connecting group. Further provided are photovoltaic cells and devices including electrode of the invention.

### FIELD OF THE INVENTION

This invention relates to electrodes, methods and systems for generating photochemical currents. The invention also concerns a process for preparing the electrodes

### BACKGROUND OF THE INVENTION

Semiconductor nanoparticles (NPs) integrated electrodes can be applied in photo electrochemical solar cell devices [1-3], photonic systems [4-6] and opteo-electronic systems [7]. Different methods were implemented in order to organize semiconductor NPs on surfaces in 2D and 3D arrays [8-9], including: covalent bonding of functionalized particles to surfaces [10-11], the layer-by-layer deposition of NPs by electrostatic interactions [12-14] or molecular bridges that include appropriate functionalities that selectively bind to the NPs [15], and the aggregation of NPs by complementary supra molecular interactions [16-17]. Additionally, processes involving electropolymerization of functionalized semiconductor NPs on electrodes [18], and the bridging of NPs onto electrodes by complementary interactions of biomolecule-functionalized NPs (e.g. complementary nucleic acids), were used to assemble semiconductor NPs on electrodes [19].

One way to enhance the light-to-electrical energy conversion yield of semiconductor nanoparticles (NPs) integrated electrodes is by increasing the charge separation yield of the electron-hole pair in the conduction-band and/or valence band levels of the NPs. Until now, different methods were reported using hybrid nanostructures consisting of NP-NP [20-24], NP-carbon nanotubes [25-26], NP-polymers [27-31] or NP-molecular relay hybrid systems [32-36] (e.g., semiconductor-metal hybrid NPs linked to C₆₀ units). Additional methods for facilitating charge separation and enhancing photocurrent generation of NP integrated electrodes included using semiconductor composites (e.g., CdSe/TiO₂ [37], CdS/SnO₂ [38] or core-shell NPs [39]), and crosslinking of NP monolayers onto electrodes by charge carrying oligomeric units (such as oligoaniline).

Previously it was demonstrated [40] that linking CdS NPs to electrodes by oligoaniline bridging units enhanced the intensity of the generated photocurrent as compared with electrodes linked with CdS NPs through alkyl chains. However, since the CdS NPs were non-conductive in nature, only a monolayer of such NPs could be associated with the electrode surface in order to achieve a photocurrent.

It is therefore an object of the present invention to provide an electrode having an electro conductive surface linked to a three dimensional matrix comprising a plurality of semiconductor and noble metal NPs, linked (NPs to each other in matrix and matrix to surface) through electropolymerizable linker (bridging) groups, wherein said linking groups are electroactive by being capable of transferring electrons between linked nanoparticles and between nanoparticles and said surface.

### REFERENCES

1. A. Hagfeldt, M. Graetzel, Chem. Rev. 1995, 95, 49.
2. P. V. Kamat, Chem. Rev. 1993, 120, 7847.
3. P. V. Kamat, J. Phys. Chem. C 2007, 111, 2834.
4. N. D. Kumar, M. P. Joshi, C. S. Friend, P. N. Prasad, Appl. Phys. Lett. 1997, 71, 1388.
5. V. L. Colvin, M. C. Schlamp, A. P. Alivisatos, Nature 1994, 370, 354.
6. B. O. Dabbousi, M. G. Bawendi, O. Onitsuka, M. F. Rubner, Appl. Phys. Lett. 1995, 66, 1316.
7. T. Cassagneau, T. E. Mallouk, J. H. Fendler, J. Am. Chem. Soc. 1998, 120, 7847.
8. A. N. Shipway, E. Katz, I. Willner, Chem Phys Chem 2000, 1,18.
9. A. N. Shipway, I. Willner, Chem. Com. 2001, 2035.
10. M. D. Musick, C. D. Keating, M. H. Keffe, M. J. Natan, Chem. Mater. 1997, 9, 1499.
11. M. Brust, D. Bethell, C. J. Kiely, D. J. Schiffrin, Langmuir 1998, 14,5425.
12. R. Blonder, L. Sheeney-Haj-Ichia, I. Willner, Chem. Com. 1998, 1393.
13. M. Lahav, R. Gabai, A. N. Shipway, I. Willner, Chem. Com. 1999, 1937.
14. A. N. Shipway, M. Lahav, R. Blonder, 1. Willner, Chem. Mater. 1999, 11, 13.
15. P. V. Kamat, S. Barazzouk, S. Hotchandani, Angew. Chem. Int. Ed. 2002, 41,2764.
16. R. Baron, C. Huang, D. M. Bassani, A. Onopriyenko, M. Zayats, I. Willner, I. Angew. Chem. Int. Ed. 2005, 44,4010.
17. J. Xu, Y. Weizmann, N. Krikhely, R. Baron, I. Willner, Small 2006, 2, 1178.
18. K. Hata, H. Fujihara, Chem. Com. 2002, 2714.
19. R. Baron, C. H. Huang, D. M. Bassani, A. Onopriyenko, M. Zayats, I. Willner, Angew. Chem. Int. Ed. 2005, 44, 4010.
20. E. Hao, B. Yang, J. Zhang, X. Zhang, J. Sun, J. Shen, J. Mater. Chem. 1999, 8,1327.
21. P. Yu, K. Zhu, A. G. Norman, S. Ferrere, A. J. Frank, A. J. Nozik, J. Phys. Chem. B 2006, 110, 25455;
22. Y. Tian, T. Newton, N. A. Kotov, D. M. GuIdi, J. H. Fendler, J. Phys. Chem. 1996, 100,8927.
23. I. Bedja, P. V. Kamat, J. Phys. Chem. 1995, 99,9182.
24. K. Rajeshwar, N. R. de Tacconi, C. R. Chenthamarakshan, Chem. Mater. 2001, 13, 2765.
25. I. Robel, B. Bunker, P. V. Kamat, Adv. Mater. 2005, 17, 2458;
26. Sheeney-Haj-Ichia, B. Basnar, I. Willner, Angew. Chem. Int. Ed. 2005, 44, 78.
27. C. W. Tang, Appl. Phys. Lett. 1986, 48, 183.
28. A. J. Heeger, J. Phys. Chem. B 2001, 105, 8475.
29. A. J. Breeze, Z. Schlesinger, S. A. Carter, P. J. Brock, Phys. Rev. B 2001, 64, art. no.-125205;
30. H. Hoppe, N. S. Sariciftci, J. Mater. Res. 2004, 19, 1924;
31. W. U. Huynh, J. J. Dittmer, A. P. Alivisatos, Science 2002, 295, 2425.
32. H. Imahori, S. Fukuzumi, Adv. Mater. 2001, 3, 1197.
33. H. Yanada, Imahori, Y. Nishimura, I. Yamazaki, S. Fukuzumi, Adv. Mater. 2002, 14,892.
34. L. Sheeney-Haj-Ichia, J. Wassermann, I. Willner, Adv. Mater. 2002, 14, 1323.
35. L. Sheeney-Haj-Ichia, I. Willner, J. Phys. Chem. B 2002, 106,13094.
36. V. Subramanian, E. E. Wolf, P. V. Kamat, J. Am. Chem. Soc. 2004, 126,4943.
37. I. Robel, V. Subramanian, M. Kuno, P. V. Kamat, J. Am. Chem. Soc. 2006, 128,2385.
38. C. Nasr, S. Hotchandani, W. Y. Kim, R. H. Schmehl, P. V. Kamat, J. Phys. Chem. B 1997, 101,7480.
39. A. Zaban, S. G. Chen, S. Chappel, B. A. Gregg, Chem. Com. 2000, 2231.
40. Granot, F. Patolsky, I. Willner, J. Phys. Chem. B 2004, 108,5875.
41. M. Riskin, R. Tel-Vered, T. Bourenko, E. Granot, I. Willner, J. Am. Chem. Soc. 2008, 130, 9726-9733
42. G. Wulff, Angew. Chem. Int. Ed. 1995, 34, 1812.
43. G. Wulff, Chem. Rev. 2002, 102, 1.
44. K. Mosbach, Trends in Biochemical Sciences, 1994, 19, 9.
45. K. Haupt, K. Mosbach, Chem. Rev. 2000, 100, 2495.
46. A. Bossi, F. Bonini, A. P. F. Turner, S. A. Piletsky, Biosens. Bioelectron. 2007, 22, 1131.
47. J. L. Suarez-Rodrigez, M. Diaz-Garcia, Biosens. Bioelectron. 2001, 16, 955.
48. I. Surugiu, J. Svitel, L. Ye, Haupt, B. Danielsonn, Anal. Chem. 2001, 73,4388.
49. N. Kirsch, J. P. Hart, D. J. Bird, R. W. Luxton, D. V. McCalley, Analyst 2001, 126, 1936.
50. M. Lahav, A. B. Kharitonov, O. Katz, T. Kunitake, I. Willner, Anal. Chem. 2001, 73,720.
51. M. Zayats, M. Lahav, A. B. Kharitonov, I. Willner, Tetrahedron 2002, 58, 815.
52. S. P. Pogorelova, M. Zayats, T. Bourenko, A. B. Kharitonov, O. Lioubashevski, E. Katz, I. Willner, Anal. Chem. 2003, 75, 509.
53. S. P. Pogorelova, Bourenko, A. B. Kharitonov, I. Willner, Analyst 2002, 591,63.
54. V. Bajpai, P. He, L. Dai, Adv. Funct. Mater. 2004, 14, 145.
55. K. Severin, Molec. Imp. Mater. 2005, 619.
56. M. Riskin, R. Tel-Vered, I. Willner. Adv. Funct. Mater. 2007, 17, 3858.

### SUMMARY OF THE INVENTION

The present invention provides electrodes useful for generating a photocurrent and devices comprising them.

In accordance with one aspect of the invention there is provided an electrode comprising a conductive surface connected to a matrix; said matrix comprising a plurality of semiconductor nanoparticles and noble metal nanoparticles; wherein substantially each nanoparticle of said plurality of nanoparticles is connected to another nanoparticle of said plurality of nanoparticles by at least one matrix connecting group capable of mediating electron transfer between nanoparticles of the matrix; and at least a portion of said plurality of nanoparticles of said matrix is each connected to said conductive surface by at least one surface connecting group, capable of mediating electron transfer between the matrix and said conductive surface.

The term “electrode” as used herein should be understood to encompass a device with an electrically conducting assembly. This assembly, in accordance with the invention, comprises a matrix having a plurality of semiconductor and noble metal nanoparticles (NPs) connected to one another and to the conductive surface. In a specific embodiment of the invention the electrode is a light sensitive electrode capable of transforming photonic energy into electrical energy, employing photo-electrochemical processes wherein there is photo excitation of semiconductor NPs and generation of an electron-hole pair in the conduction-band and valence band levels, respectively. The ejection of the conduction-band electrons to the electrode's conductive surface, or alternatively their ejection to a solution-solubilized with electron acceptor groups yields anodic or cathodic photocurrents, respectively.

A conductive surface employed by an electrode of the invention may be any conductive metal surface such as for example gold, platinum, silver, suitable alloys, etc or any alloy or combination thereof. The conductive surface of the invention may also be made of conductive materials other than pure metal such as, for example graphite, Indium-Tin-Oxide (ITO), etc. The electrical responsiveness of the electrode depends, among others, on the surface area of the conducting surface. According to some embodiments the surface area is increased by roughening or the use of a porous surface. It should be noted that through such increase in specific surface area the overall size or dimensions of the electrode may be decreased. A conductive surface employed by an electrode of the invention may be in any shape or form, such as for example in a flat, sheet like structure or as a three dimensional body having a top, bottom and side faces which may all or partially be conductive.

The matrix structure carried on or connected to said conductive surface of an electrode of the invention comprises a plurality of at least one type of semiconductor NPs and a plurality of at least one type noble metal NPs, wherein substantially each of said NPs of matrix are connected through at least one type of matrix connecting group. The matrix components described above may be structured in any two or three dimensional form structure. It should be understood that the components of the matrix (i.e. plurality of nanoparticles connected by matrix connecting groups) may be formed in an ordered, non-ordered or amorfic forms. In one embodiment a matrix of an electrode of the invention comprising a plurality of semiconductor nanoparticles and noble metal nanoparticles; wherein substantially each semiconductor nanoparticle of said plurality of nanoparticles is connected to at least one noble metal nanoparticle by at least one matrix connecting group in a heterogeneous, non-ordered structure (wherein no layer of a single type of nanoparticle is formed). The matrix structure may be constructed through electrochemical processes involving the components of the matrix, such as electropolymerization processes.

The matrix is associated with the conductive surface by surface connecting groups, which may be the same or different than the matrix connecting groups. The association of the matrix to the conductive surface may also be achieved through the use of electrochemical processes indicated above. In one embodiment said matrix is fabricated in situ on said conductive surface, using electropolymerization processes, thereby forming an electrode of the invention.

The term “a plurality of semiconductor and noble metal nanoparticles” should be understood to encompass any combination of semiconductor nanoparticles and noble metal nanoparticles. The semiconductor nanoparticles may comprise at least one type of nanoparticles of a semiconductor substance. Similarly, the noble metal nanoparticles may comprise at least one type of nanoparticles of a noble metal substance. In another embodiment the matrix may comprise two or more types (species) of semiconductor nanoparticles and two or more types of noble metal nanoparticles.

As used herein the term “nanoparticles” (NPs) refers to any particle for which at least one dimension of the particles (diameter, width) has a size in the range of about 1 nm to 200 nm. The term also refers to particles having any shape such as spherical, elongated, cylindrical, or to amorphous nanoparticles. Semiconductor nanoparticles may have the same or different shape/size than the shape and/or size of the noble metal nanoparticles. In case two or more types of semiconductor and/or noble metal nanoparticles construct the matrix of an electrode of the invention, each type may have the same or different size and/or shape.

Semiconductor NPs used herein encompass any semiconductor substance (being a composite material or a single atomic material) having an intermediate conductivity value (i.e. between the conductivity value of a good conductive substance, e.g. metal, and the conductivity value of an insulator), having a band gap between the valance and conduction bands of between about 4 eV.

Semiconductor nanoparticles may comprise elements of Group II-VI, such as CdSe, CdS, CdTe, ZnSe, ZnS, ZnTe, HgS, HgSe, HgTe and alloys thereof such as CdZnSe; Group III-V, such as InAs, InP, GaAs, GaP, InN, GaN, InSb, GaSb, AlP, AlAs, AlSb and alloys such as InAsP, CdSeTe, ZnCdSe, InGaAs; Group IV-VI, such as PbSe, PbTe and PbS and alloys thereof; Group such as InSe, InTe, InS, GaSe and alloys such as InGaSe, InSeS; Group IV semiconductors, such as Si and Ge alloys thereof, and combinations thereof in composite structures and core/shell structures. In one embodiment semiconductor NPs are selected from cadmium sulfide, cadmium selenide, cadmium telluride, indium selenide or any combinations thereof. At least one dimension of a semiconductor nanoparticle employed by the invention may range from about 1.5 nm to 100 nm.

Noble metal nanoparticles, as used herein, include any noble metal nanoparticles that are resistant to corrosion, oxidation and any type of tarnishing wherein their conductive properties provide a conductive array for the build-up of the semiconductor NPs in a matrix of an electrode of the invention, and thus allow coverage of semiconductor NPs on said conductive surface of an electrode of the invention, beyond a monolayer of semiconductor NPs. Additionally, noble metal NPs in the matrix of the invention may trap conduction band electrons and act as charge transport units to the conductive surface of the electrode of the invention.

In one embodiment, the noble metal nanoparticles are selected from ruthenium, rhodium, palladium, silver, osmium, iridium, platinum and gold or any combinations thereof. At least one dimension of a noble metal nanoparticle employed by the invention may range from about 2 nm to 150 nm.

In a further embodiment the molar ratio (for example for n_{CdS}/n_{Au}) between the semiconductor nanoparticles and the noble metal nanoparticles in a matrix of an electrode of the invention is between about 0.1 to about 10.0 In one embodiment, said molar ratio (for example for n_{CdS}/n_{Au}) between semiconductor nanoparticles and noble metal nanoparticles in the matrix that is about 3.0. Without being bound by theory it should be noted that the molar ratio between semiconductor nanoparticles and noble metal nanoparticles in a matrix of an electrode of the invention controls the efficiency of the electrode and/or photoelectron device. Thus, the effective ratio varies from system to system depending on the relative sizes of the different nanoparticles employed in the matrix, and the chemical nature of the different noble metal or semiconductor nanoparticles.

As defined hereinabove substantially each of said nanoparticles of said plurality of nanoparticles of the matrix of an electrode of the invention are connected through at least one matrix connecting group. Thus, at least about 50 to about 100% of nanoparticles of the matrix of the invention are connected through at least one matrix connecting group as defined herein above and below.

In an electrode of the invention the matrix connecting groups are selected in accordance with their capabilities of mediating electron transfer between connected nanoparticles of said matrix. In one embodiment of the invention matrix connecting groups of an electrode of the invention comprise at least one π-conjugated electron rich moiety. In one embodiment said π-conjugated electron rich moiety may be an aromatic or non-aromatic moiety, and may also comprise one or more heteroatoms. In another embodiment, said matrix connecting group is an electropolymerized oligomer. It should be noted that each of said NPs of a matrix of an electrode of the invention may be connected through the same or different electropolymerized oligomer defined above. In a further embodiment, said electropolymerized oligomer comprises one or more optionally substituted aromatic or heteroaromatic moieties.

Furthermore, as defined hereinabove at least a portion of said plurality of nanoparticles of a matrix of an electrode of the invention are connected to a conductive surface of an electrode of the invention through at least one surface connecting group, which are selected in accordance with their capabilities of mediating electron transfer between the matrix and said conductive surface. The term “at least a portion” should be understood to mean that at least a part of the nanoparticles of the matrix which are closer to the conductive surface are attached thereto via said surface connecting groups. The close proximity of said portion of nanoparticles of the matrix may be from one dimension of the conductive surface the outer surface (for example from either side of the conductive surface), from two dimensions of the conductive surface (for example from two sides of the conductive surface) or from three dimensions of the conductive surface (for example surrounding the conductive surface either partially or completely). In one embodiment the portion of the nanoparticles of the matrix connected to conductive surface via surface connecting group maintains the molar ratio between semiconductor nanoparticles and noble metal nanoparticles of the whole matrix. In one embodiment at least a portion of the nanoparticles at the outer boundaries of said matrix are connected to said conductive surface via said surface connecting groups. Said matrix connecting groups may be the same of different than said surface connecting groups.

In one embodiment of the invention surface connecting groups of an electrode of the invention comprise at least one π-conjugated electron rich moiety. In one embodiment said π-conjugated electron rich moiety may be an aromatic or non-aromatic moiety, and may also comprise heteroatoms. In another embodiment of the invention said surface connecting group is an electropolymerized oligomer. It should be noted that each of said at least a portion of nanoparticles of a matrix NPs of a matrix of an electrode of the invention may be connected through the same or different electropolymerized oligomer defined above. In a further embodiment, said electropolymerized oligomer comprises one or more optionally substituted aromatic or heteroaromatic moieties.

The term “electropolymerized oligomer” is meant to encompass an oligomer produced by electropolymerization processes of at least one electropolymerizable monomer. An electropolymerized oligomer may comprise 2, 3, 4, 5, 6, 7, 8, 9, 10 electropolymerized monomer units. In a further embodiment an electropolymerizable monomer forming electropolymerized oligomer is selected from thioaniline, thiophenol, 2-amino-thiophenol, 3-amino-thiophenol, 4-amino-thiophenol, thiopyrrol, thiofuran, thiophene and any combinations thereof.

In another embodiment said electropolymerized oligomer of a matrix connecting group comprises at least two anchoring groups which may be the same or different and are each independently chemically associated with at least one nanoparticle of the matrix. Said anchoring groups of an electropolymerized oligomer may be any group capable of associating to an NP though either through chemical bound(s) or by sorption association. In one embodiment said anchoring group is selected from S—, —NH₂ and —CO₂⁻.

In one embodiment of the invention a matrix connecting group is a group of the formula (I):

Z₁-L₁-Z₂ (I)

wherein each of the Z₁ and Z₂, which may be the same or different, is a bond or a moiety that are each independently chemically associated with at least one nanoparticle; and L₁ is a linker group comprising at least one electropolymerized monomer or oligomer thereof.

In another embodiment L₁ comprises one or more optionally substituted aromatic or heteroaromatic moieties. In a further embodiment said electropolymerized monomer is selected from a group consisting of thioaniline, thiophenol, 2-amino-thiophenol, 3-amino-thiophenol, 4-amino-thiophenol, thiopyrrol or any combinations thereof.

In a further embodiment said electropolymerized oligomer of a surface connecting group comprises at least two anchoring groups which may be the same or different and are each independently chemically associated with at least one nanoparticle of the matrix and/or conductive surface. In another embodiment said electropolymerized oligomer of a surface connecting group comprises one or more optionally substituted aromatic or heteroaromatic moieties.

In another embodiment said surface connecting group is a group of the formula (II):

Z₃-L₂-Z₄ (II)

wherein each of the Z₃ and Z₄, which may be the same or different, is a bond or a moiety that are each independently chemically associated with at least one nanoparticle or conductive surface; and

L₂ is a linker group comprising at least one electropolymerized monomer or oligomer thereof.

In one embodiment L₂ comprises one or more optionally substituted aromatic or heteroaromatic moieties. In another embodiment electropolymerized monomer is selected from a group consisting of thioaniline, thiophenol, 2-amino-thiophenol, 3-amino-thiophenol, 4-amino-thiophenol, thiopyrrol or any combinations thereof.

In one embodiment each of Z₁, Z₂, Z₃ and Z₄ may independently be selected from S—, —NH₂ and —CO₂⁻. In one embodiment Z₁, Z₂, Z₃ and Z₄ are the same. In another embodiment L₁ and L₂ are the same.

The term “chemically associated” is meant to encompass any type of chemical connection which may be a chemical bond or a sorption association between e.g. an anchoring group of a matrix connecting group and a NP, an anchoring group and of a surface connecting group and a NP, an anchoring group of a surface connecting group and a conductive surface, between Z₁ and/or Z₂ and a NP, between Z₃ and/or Z₄ and a NP or a conductive surface. The terms “bind”, “bond”, “bound” or “chemical bond” or any of their lingual derivatives refer to any form of establishing a substantially stable connection between different components (such as for example a NP and/or the conductive surface of an electrode of the invention) and an anchoring moiety of a surface connecting group and/or a matrix connecting group. A bond may include, for example, a single, double or triple covalent bond, complex bond, electrostatic bond, Van-Der-Waals bond, hydrogen bond, ionic bond, π-interactions, donor-acceptor interactions or any combination thereof.

When referring to the term “sorb” or “sorbed” or any of their lingual derivatives it should be understood to encompass the occlusion of a moiety of a surface and/or matrix connecting group by means of absorption and/or adsorption and a component of a matrix and/or conductive surface of an electrode of the invention.

In one embodiment Z₁ of a matrix connecting group is chemically associated with a semiconductor NP while Z₂ is chemically associated with a noble metal NP. In another embodiment Z₁ of a matrix connecting group is chemically associated with a semiconductor NP while Z₂ is chemically associated with another semiconductor NP. In a further embodiment Z₁ of a matrix connecting group is chemically associated with a noble metal NP while Z₂ is chemically associated with a noble metal NP.

In one embodiment Z₃ of a surface connecting group is connected to a semiconductor NP and Z₄ is connected to a conductive surface of an electrode of the invention. In another embodiment Z₃ of a surface connecting group is connected to a noble metal NP and Z₄ is connected to a conductive surface of an electrode of the invention. In one embodiment Z₄ of a surface connecting group is connected to a semiconductor NP and Z₃ is connected to a conductive surface of an electrode of the invention. In another embodiment Z₄ of a surface connecting group is connected to a noble metal NP and Z₃ is connected to a conductive surface of an electrode of the invention.

The term “optionally substituted aromatic or heteroaromatic moieties” should be understood to encompass an optionally substituted 5-12 membered aromatic or heteroaromatic ring systems. In one embodiment said ring systems is an optionally substituted fused aromatic or heteroaromatic ring systems. In another embodiment said ring system comprises at least two optionally substituted 5-12 membered aromatic or heteroaromatic moieties bonded to each other via at least one chemical bond (for example a single, double or triple bond). In yet another embodiment said ring system comprises at least two optionally substituted 5-12 membered aromatic or heteroaromatic moieties bonded to each other via at least one spacer moiety (for example —NH—, —O—, —S—, —NR— etc). In a further embodiment said ring system comprises at least two optionally substituted 5-12 membered aromatic or heteroaromatic moieties connected via π-π interaction. Optional substitution on an aromatic or heteroaromatic moieties include at least one of —NH₂, —NHR, —NR₂, —OH, —OR, —SH, —SR, wherein R is a C₁-C₁₂ alkyl or any other electron releasing group (including halo, phenyl, amine, hydroxyl, O⁻, etc.), substituted at any position of the aromatic or heteroaromatic moiety. Non limiting list of aromatic or heteroaromatic optionally substituted moieties include: phenylene, aniline, phenolynene, pyrrolynene, furynene, thiophenylene, benzofurylene, indolynene.

In one embodiment an electropolymerizable monomer of an electropolymerized oligomer of a matrix connecting group is p-thioaniline. In another embodiment of the invention a matrix connecting group of formula (I) is oligothianiline having 2, 3, 4, 5, 6, 7, 8, 9, 10 p-thioaniline (4-amino-thiophenol) monomer units electropolymerized to form a matrix defined above. In another embodiment said oligothioaniline is a group of formula (VII):

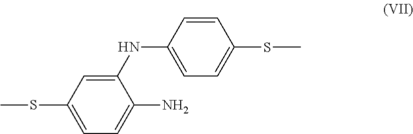

wherein each of the S moieties are independently chemically sorbed to two semiconductor NPs/a semiconductor NP and a noble metal NP/two noble metal NPs, all as defined herein above. Each NP may be further connected through the same or different matrix connecting groups to other NPs.

In another embodiment an electropolymerizable monomer of an electropolymerized oligomer of a surface connecting group is p-thioaniline. In another embodiment of the invention a surface connecting group of formula (II) is oligothianiline having 2, 3, 4, 5, 6, 7, 8, 9, 10 p-thioaniline (4-amino-thiophenol) monomer units electropolymerized to connect said a portion of nanoparticles of a matrix of an electrode of the invention to a conductive surface of an electrode of the invention. In another embodiment said oligothioaniline is a group of formula (VII) above, wherein each of the S moieties are independently chemically sorbed to a conductive surface and semiconductor NP/a conductive surface and noble metal NP all as defined herein above. Each NP may be further connected through the same or different matrix connecting groups to other NPs.

Upon photochemical induction of an electrode of the invention (in the presence of an external electron donor, e.g. in a surrounding solution, which may be sacrificial electron donor such as triethanolamin, or a reversible one, such as I₃⁻), a charge transfer sequence along the components of the matrix (including the NPs and the matrix connecting groups) is directed either to the connected conductive surface or away from the connected conductive surface. In a further embodiment of the invention the transfer of electrons mediated by a connecting group is achieved through charge-hopping or electron tunneling.

In another embodiment the electrode of the invention comprises at least one electron acceptor molecule having a redox potential that is more positive than the conductive band of semiconductor nanoparticles in the matrix of an electrode of the invention. In one embodiment said electron acceptor group is selected from a group consisting of N,N′-dimethyl-4,4′-bipyridinium, quinone and a transition metal complex exhibiting electron acceptor properties such as ferric cyanide or molybdenum cyanide or any combinations thereof.

In another one of its aspects the invention provides a photovoltaic cell comprising an electrode of the invention.

In a further aspect of the invention there is provided a device comprising a photo-sensitive electrode, said electrode being an electrode of the invention.

In another one of its aspects the invention provides a process of preparing an electrode comprising:
forming a layer on a conductive surface comprising at least one electropolymerizable group having the general formula (V):

Z₃-L₂ (V)
wherein Z₃ is a bond or a moiety that is chemically associated with the conductive surface; and L₂ is a linker group comprising at least one electropolymerized monomer or oligomer thereof;
contacting the layered conductive surface with a plurality of semiconductor nanoparticles and noble metal nanoparticles, each independently being chemically associated with at least one electropolymerizable group having the general formula (VI):

Z₁-L₁ (VI)
wherein Z₁ is a bond or a moiety that is chemically associated with the nanoparticle; and L₁ is a linker group comprising at least one electropolymerized monomer or oligomer thereof; and
electropolymerizing said plurality of nanoparticles and said layered surface to form an electrode comprising a conductive surface connected to a matrix;

wherein said matrix comprising a plurality of semiconductor nanoparticles and noble metal nanoparticles; and

wherein substantially each nanoparticle of said plurality of nanoparticles is connected to another nanoparticle of said plurality of nanoparticles by at least one electropolymerized group; and at least a portion of said plurality of nanoparticles of said matrix is each connected to said conductive surface by at least one electropolymerized group.

In one embodiment L₁ and L₂ each independently comprise one or more optionally substituted aromatic or heteroaromatic moieties. In another embodiment L₁ and L₂ are each independently an electropolymerized monomer selected from thioaniline, thiophenol, 2-amino-thiophenol, 3-amino-thiophenol, 4-amino-thiophenol, thiopyrrol or any combinations thereof. In one embodiment of a process of this invention, Z₁ and Z₃ are the same. In a further embodiment of a process of the invention L₁ and L₂ are the same.

The formation of a layer of at least one electropolymerizable group having the general formula (V) on a conductive surface can be performed by reacting the conductive surface with a solution comprising a precursor of an electropolymerizable group. In one embodiment said precursor is p-aminothiophenol, forming a thioaniline layer on a conductive surface. In one embodiment of a process of the invention the semiconductor nanoparticles are chemically bonded or sorbed with at least one thioaniline group. In a further embodiment of a process of the invention the noble nanoparticles are chemically bonded or sorbed with at least one thioaniline group.

Electropolymerization processes used in the process of the invention relate to the 10-100 repetitive cyclic voltammetry scans of a mixture of a plurality of semiconductor NPs having chemically bonded or sorbed thereon at least one electropolymerizable group of the general formula (VI), a plurality of noble metal NPs having chemically bonded or sorbed thereon the same or different at least one electropolymerizable group of the general formula (VI) and a conductive surface having chemically bonded or sorbed thereon at least one electropolymerizable group having the general formula (V). In one embodiment 10 repetitive cyclic voltammetry scans are performed. In another embodiment 20 repetitive cyclic voltammetry scans are performed. In yet a further embodiment 40 repetitive cyclic voltammetry scans are performed. In another embodiment 60 repetitive cyclic voltammetry scans are performed. In a further embodiment 80 repetitive cyclic voltammetry scans are performed. In one embodiment 100 repetitive cyclic voltammetry scans are performed. In another embodiment the mixture of said nanoparticles and said layered surface has a pH of between about 7 to about 10.

In one other embodiment of a process of the invention, said electropolymerizing process is performed in the presence of at least one electron acceptor molecule having a redox potential that is more positive than the conductive band of said semiconductor nanoparticles, thereby imprinting molecular recognition sites in the matrix of an electrode of the invention.

Without being bound by theory, such molecular recognition sited in a matrix of an electrode of the invention enhances the binding of the electron acceptor molecules to the NPs connected matrix, acting synergistically to the π donor-acceptor interactions in associating the electron acceptor molecules to NPs of the matrix of an electrode of the invention.

In another embodiment of a process of the invention at least one electron acceptor group having a redox potential that is more positive than the conductive band of said semiconductor nanoparticles is added following electropolymerization step.

In a further embodiment of a process of the invention, said electron acceptor is selected from the group consisting of N,N′-dimethyl-4,4′-bipyridinium, quinone and a transition metal complex exhibiting electron acceptor properties such as ferric cyanide or molybdenum cyanide or any combinations thereof. In one embodiment the electron acceptor is N,N′-dimethyl-4,4′-bipyridinium (MV²⁺). In a further embodiment MV²⁺ is present in a concentration of between about 0.1 to about 4.0 mM.

### BRIEF DESCRIPTION OF THE DRAWINGS

In order to understand the invention and to see how it may be carried out in practice, embodiments will now be described, by way of non-limiting example only, with reference to the accompanying drawings, in which:

FIG. 1A is a schematic illustration of the synthesis of a 3D oligoaniline-crosslinked Au/CdS NPs array by the electropolymerization of the thioaniline-nanoparticles on the thioaniline-electrodes.

FIG. 1B is a schematic illustration of the photo-induced charge transfer along the oligoaniline-connected Au/CdS nanoparticle array, in the presence of the sacrificial electron donor, triethanolamine.

FIG. 2 schematically depicts the potential-controlled electron transport across the 3D oligoaniline-crosslinked Au/CdS nanoparticle array, in the presence of methyl viologen, MV²⁺, as the electron acceptor.

FIG. 3 shows the photocurrent action spectra of the oligoaniline-bridged CdS-NPs modified Au electrodes generated by variable numbers of electrochemical deposition cycles: a) 20; b) 40; c) 60; d) 80; e) 100 cycles. Electropolymerization was performed in the presence of 0.1 M phosphate buffer, pH=7.4. Photocurrents were recorded in 0.1 M phosphate buffer, pH=11.5, in the presence of 20 mM triethanolamine.

FIG. 4A shows the photocurrent action spectra of the oligoaniline-crosslinked Au/CdS NPs modified Au electrodes, generated using different molar ratios of the thioaniline-CdS NPs and the thioaniline-Au NPs, n_{CdS}/n_{Au}: a) 0.2; b) 0.33; c) 0.5; d) 1.0; e) 2.0; f) 3.0; g) 4.0 and, h) 5.0. Electropolymerization was performed using 40 repetitive voltammetry scans in the presence of 0.1 M phosphate buffer, pH=7.4, that included 1 mg ml⁻¹ Au nanoparticles and the CdS NPs according to the indicated molar ratios. Photocurrents were recorded in 0.1 M phosphate buffer, pH=11.5, in the presence of 20 mM triethanolamine.

FIG. 4B shows the photocurrent action spectra of the oligoaniline-crosslinked Au/CdS NPs-modified Au electrode generated by a variable number of electrochemical deposition cycles: a) 20; b) 40; c) 60; d) 80; e) 100 cycles. Electropolymerization was performed in the presence of 0.1 M phosphate buffer, pH=7.4, that included 10.4 mg⁻¹ CdS NPs and 1 mg ml⁻¹ Au NPs (n_{CdS}/n_{Au}=3). Photocurrents were recorded in 0.1 M phosphate buffer, pH=11.5 the presence of 20 mM triethanolamine.

FIG. 4C shows the photocurrent intensities, at λ=400 nm, generated by the Au/CdS NPs-modified electrode following electropolymerization at the respective ratios of the two NPs materials (as mentioned and under the conditions in FIG. 4(A) above).

FIG. 4D shows the photocurrent intensities, at λ=400 nm, generated by Au surfaces subjected to variable numbers of electropolymerization cycles, for assemblies corresponding to: a) the oligoaniline-crosslinked CdS NPs-modified Au electrodes; b) the oligoaniline-crosslinked Au/CdS NPs-modified Au electrode.

FIG. 5 demonstrates the microgravimetric quartz crystal microbalance (QCM) analysis of nano-particle functionalized Au/quartz crystals generated by variable numbers of electropolymerization cycles: a) The oligoaniline-bridged CdS NPs-modified Au electrode; b) The oligoaniline crosslinked Au/CdS NPs-modified Au electrode; c) The oligoaniline-crosslinked Au NPs modified Au electrode. Curve (d) corresponds to the subtraction of curve (c) from curve (b) and correlates to the frequency changes by the CdS NPs in the Au/CdS NPs composite. The geometrical area of the Au electrode was 0.2±0.05 cm².

FIG. 6A shows the potential-dependent photocurrent values at λ=400 nm generated by the oligoaniline-crosslinked Au/CdS NPs-modified Au electrode. The electrolyte solution consisted of 0.1 M phosphate buffer solution at pH=11.5. Scan rate is 100 mV S⁻¹. Prior to the measurement, the solution was bubbled with Argon for 15 minutes.

FIG. 6B shows a cyclic voltammogram corresponding to the electrochemically generated, oligoaniline-crosslinked Au/CdS NPs modified Au electrode. The electrolyte solution consisted of 0.1 M phosphate buffer solution at pH=11.5. Scan rate is 100 mV S⁻¹. Prior to the measurement, the solution was bubbled with Argon for 15 minutes.

FIG. 7A demonstrates the photocurrent action spectra of the oligoaniline-crosslinked Au/CdS NPs modified Au electrode, in the presence of variable concentrations of the electron acceptor, MV⁺²: a) 0; b) 0.2; c) 0.4; d) 0.75; e) 1.0; f) 2.0 mM. Photocurrents were recorded in 0.1 M phosphate buffer, pH=11.5, in the presence of 20 mM triethanolamine.

FIG. 7B Photocurrent action spectra of the oligoaniline-crosslinked Au/CdS NPs-modified Au electrodes in the following configurations: a) The non-imprinted electrode, in the absence of MV⁺² in solution; b) The non-imprinted electrode, in the presence of 0.2 mM MV²⁺ in solution; c) The MV⁺²-imprinted electrode, in the presence of 0.2 mM MV⁺² in solution. Photocurrents were recorded in 0.1 M phosphate buffer, ph=11.5, in the presence of 20 mM triethanolamine.

FIG. 8 shows the potential-dependent photocurrents, at λ=400 nm, generated by the oligoaniline crosslinked Au/CdS NPs-modified Au electrode, in the presence of 2 mM MV²⁺ and 20 mM triethanolamine in 0.1 M phosphate buffer, pH=11.5, upon the application of different potentials on the electrode.

FIG. 9 shows the photocurrent action spectra, generated by the different NPs-functionalized electrodes in the presence of I₃⁻ as the electron donor: a) The oligoaniline-crosslinked Au/CdS NPs-modified Au electrode in the absence of MV²⁺ in solution; b) the oligoaniline-bridged CdS NPs-modified Au electrode in the presence of MV²⁺, 0.2 mM; c) The oligoaniline crosslinked Au/CdS NPs-modified Au electrode in the presence of MV²⁺, 0.2 mM; d) The MV²⁺-imprinted oligoaniline-crosslinked Au/CdS NPs-modified Au electrode in the presence of MV²⁺, 0.2 mM. Photocurrents were recorded in 0.1 M phosphate buffer, pH=11.5, in the presence of 10 mM I₃⁻.

FIG. 10 shows the coulometric analysis of MV²⁺ linked to the n-donor oligoaniline units upon the interaction of electrodes consisting: (a) The Au/CdS NPs array; (b) The MV²⁺-imprinted Au/CdS NPs array, with different bulk concentrations of MV²⁺.

FIG. 11 shows the photocurrent action spectrum of thioaniline-CdS NPs linked to the Au surface by 1,4-dimercaptobutane.

FIG. 12 shows the absorption spectrum of the thioaniline-CdS NPs, 0.17 mg mL⁻¹ in 0.1 M phosphate buffer, pH=11.5.

### DETAILED DESCRIPTION OF EMBODIMENTS

In accordance with one aspect of the invention there is provided an electrode comprising a conductive surface connected to a matrix; said matrix comprising a plurality of semiconductor nanoparticles and noble metal nanoparticles; wherein substantially each nanoparticle of said plurality of nanoparticles is connected to another nanoparticle of said plurality of nanoparticles by at least one matrix connecting group capable of mediating electron transfer between nanoparticles of the matrix; and at least a portion of said plurality of nanoparticles of said matrix is each connected to said conductive surface by at least one surface connecting group, capable of mediating electron transfer between the matrix and said conductive surface.

The present invention provides a method for fabricating photoelectrochemical electrodes of the invention by the electropolymerization of functionalized noble metal NPs and semiconductor NPs on modified conductive surfaces to yield a matrix wherein noble metal NPs and semiconductor NPs are connected via connecting groups.

Within the electropolymerization process, the noble metal NPs provide conductive paths for the three-dimensional aggregation of the semiconductor NPs on the conductive surface of the electrode. The surface and/or matrix connecting groups (such as for example the oligoaniline bridging units) are capable of mediating electron transfer between connected nanoparticles and between nanoparticles and said conductive surface, either by acting as relay sites that trap the conduction band electrons, (for oligoaniline in their oxidized quinoide state), or as charge carriers in their conjugated, reduced, π-donor configuration.

The charge transport functions (mediation of electron transfer) of the surface and/or matrix connecting groups together with the high conductivity of the noble metal NPs resulted in effective charge separation and efficient photocurrent generation.

The photoelectrochemical functions of the electrode of the invention is further enhanced by incorporating at least one electron acceptor (relay) molecules (such as for example MV²⁺) into the matrix carried on said conductive surface, by π donor-acceptor interactions with a component of said matrix (either an NP of the matrix or a moiety of the connecting groups therein).

The nano-structured electrodes of the invention may be utilized for the assembly of a device such as for example a photo-electrochemical, solar cell, photonic, optoelectronic systems or devices. Furthermore the invention provides a device comprising a photo-sensitive electrode, said electrode being that of the invention.

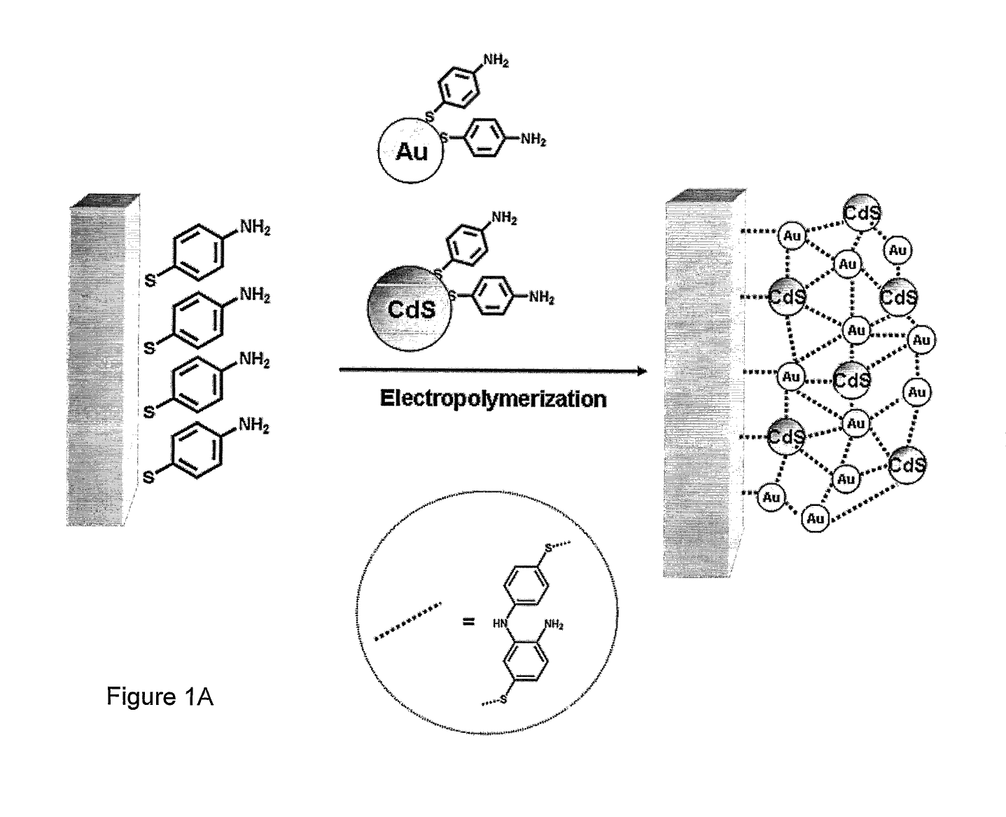

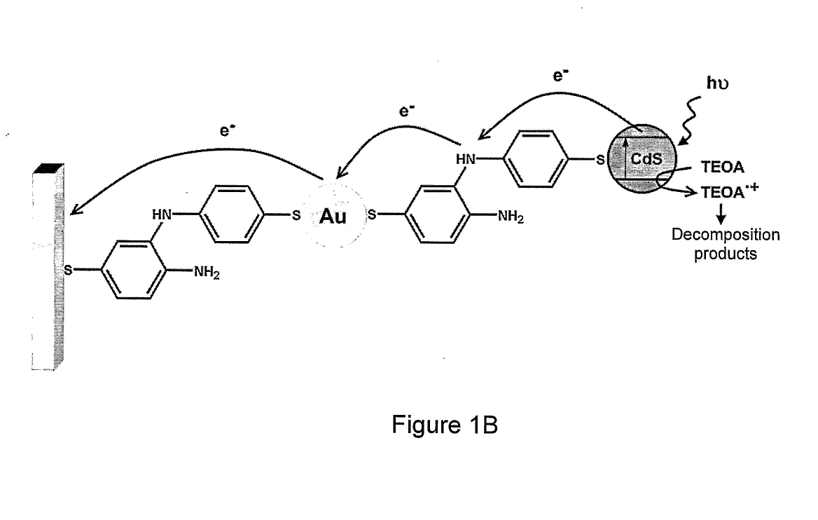

A manner of preparing an electrode in accordance with an embodiment of the invention is illustrated in FIG. 1A. In this specific example the electropolymerization process of thioaniline-Au NPs, is performed in the presence of thioaniline-CdS NPs yielding a three-dimensional Au/CdS NPs matrix.

A noble metal NP, such as for example the Au NP, own two complementary functions: (i) the electrochemical polymerization of the Au NPs provides a conductive array for the built-up of the CdS NPs on an electrode beyond a monolayer coverage; (ii) the Au NPs linked to the CdS NPs by oligoaniline bridges may act as traps for the conduction band electrons and charge transport units/connecting groups to an electrode of the invention. These functions may assist the charge separation, and thus, enhance the photocurrent intensities achieved with an electrode of the invention.

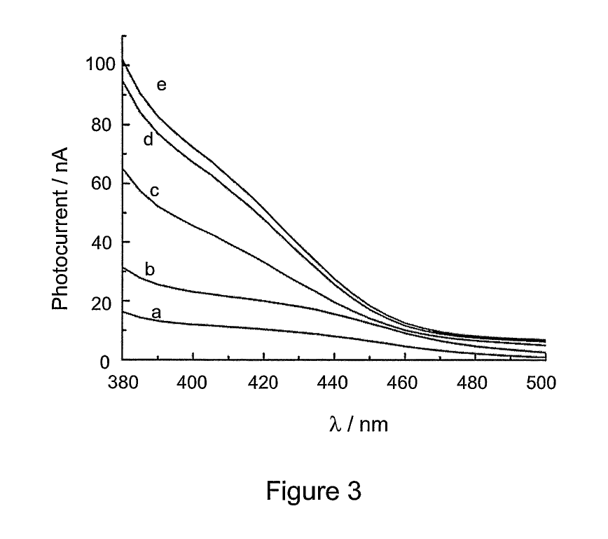

FIG. 3 depicts the photocurrent action spectra of the oligoaniline-connected CdS NPs-modified electrodes generated by different number of electropolymerization cycles, in the presence of triethanolamine as sacrificial electron donor. The photocurrent intensity at 400 nm is ca. 70 nA for the CdS NPs-modified electrode, generated by 100 electropolymerization cycles.

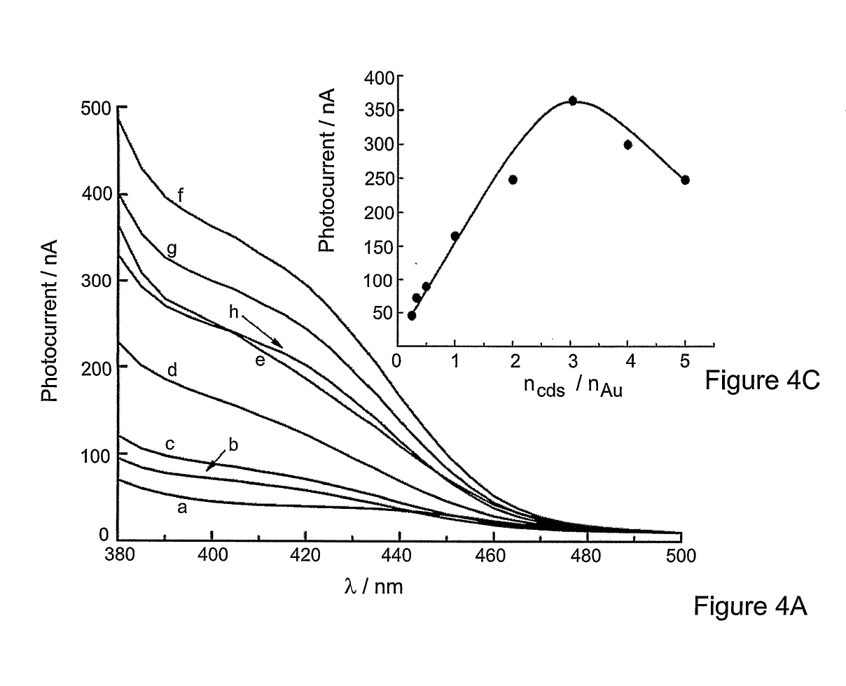

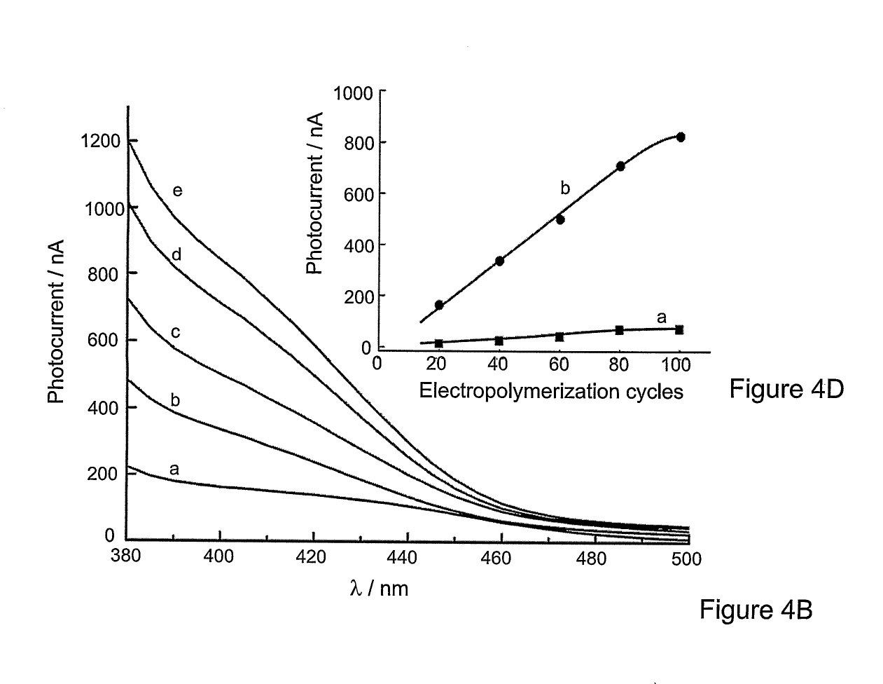

The electropolymerization of the CdS NPs in the presence of the Au NPs was conducted at variable ratios for the two types of the NPs (Au NPs, 3.5±0.5 nm, and, CdS NPs, 8.5±0.5 nm). FIG. 4A shows the photocurrent action spectra generated by Au/CdS electrodes of an embodiment of the invention fabricated by 40 electropolymerization cycles in the presence of variable ratios of the two kinds of NPs. FIG. 4C shows the photocurrent intensities at λ=400 nm for the different electrodes. The maximal photocurrent is observed for the electrode generated by the electropolymerization of CdS NPs and Au NPs at a ratio of 3:1, and the electrodes exemplified hereinbelow were prepared according to this ratio.

Without being bound by theory, the favorable ratio of CdS/Au NPs, is attributed to the balance needed: (i) for optimal conductance by the Au NPs for the effective deposition of the CdS NPs, and the subsequent transport of the conduction band electrons, and, (ii) for maximal loading of the photoactive CdS NPs the matrix.

FIG. 4B shows the photocurrent action spectra of the aggregated Au/CdS NPs electrodes of an embodiment of the invention, generated by variable numbers of electropolymerization cycles. As the number of cycles increases, the photocurrent values were intensified. For example, after 100 cycles the photocurrent at 400 nm is ca. 850 nA, whereas the CdS NPs-modified electrodes fabricated by 100 cycles yield a photocurrent of only 70 nA.

FIG. 4D compares the photocurrent values of the Au/CdS NPs electrodes of an embodiment of the invention and the CdS NPs functionalized electrode, which were generated by variable numbers of electropolymerization cycles.

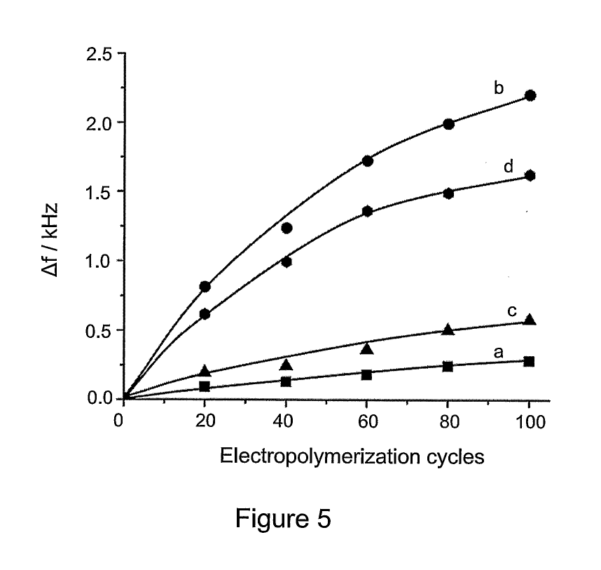

Microgravimetric quartz crystal microbalance, QCM, measurements were performed to assess the coverage of the different NPs on different exemplified electrodes. FIG. 5, curve (a), depicts the frequency change of the quartz crystal upon the electropolymerization of the CdS NPs on the thioaniline-layered Au surface associated with the crystal. After 100 electropolymerization cycles the frequency changes by 0.28 kHz. Taking into account the average size of the CdS NPs (8.5 nm), the coverage of the NPs was estimated to be 1.0×10¹² particles cm⁻². This value translated to ca. 58.4% of a random densely-packed particle monolayer.

FIG. 5, curve (b) shows the frequency changes of a quartz crystal upon formation of the Au/CdS NPs matrix as a result of application of variable numbers of electropolymerization cycles. As can be seen, the crystal frequency changes by 2.20 kHz after the application of 100 polymerization cycles.

FIG. 5, curve (c), shows the frequency changes observed upon the electropolymerization of the thioaniline-Au NPs only on the Au/quartz crystal. For example, after 100 electropolymerization cycles the frequency of the crystal changes by ca. 0.58 kHz. Taking into account the size of the particles, 3.5 nm, the coverage of aggregated particles on the surface was estimated to be 7.30×10¹² particles cm⁻².

In the assumption that the extent of coverage of the Au NPs alone is similar to the degree of Au NPs aggregation in the Au/CdS NPs system, the frequency changes observed upon the electropolymerization of the Au NPs was subtracted from the experimental frequency changes in the Au/CdS NPs system. This gave rise to FIG. 5 curve (d) that depicts the frequency changes occurring on the crystal as a result of the deposition of the CdS NPs in the aggregated matrix.

Thus, it was deducted that after 100 electropolymerization cycles the coverage of the CdS NPs corresponds to 5.91×10¹² particles cm⁻², a value that is ca. 6-fold higher than the CdS NPs coverage in the monolayer coverage. Therefore, the electropolymerization of the mixture of the Au NPs and CdS NPs enables the increase of the content of the photoactive CdS NPs.

The electropolymerization of the Au NPs provides a conductive array for the continuous growth and assembly of the CdS NPs in a three dimensional aggregated matrix structure. The photocurrent intensity in the presence of the Au/CdS NPs composite matrix is ca. 12-fold higher than the photocurrent from the CdS NPs system, a value that cannot be exclusively attributed to the increased content (absorbance) of the photoactive semiconductor particles. It should be noted that the Au NPs exhibit a plasmon absorbance in the CdS NPs absorbance region, and thus they interfere with the photosensitivity of the CdS NPs. Thus, the enhanced photocurrent in the presence of the Au/CdS NPs composite matrix is not only attributed to the higher content of the CdS NPs, but also to the enhanced charge separation stimulated by the oligoaniline connecting groups, which trap the conduction-band electrons and act as charge carriers of the electrons to the electrodes, as illustrated in FIG. 1B. Without being bound by theory, the efficient trapping/transport of the electrons retards the electron-hole recombination, thus leads to the high photocurrent values.

The quantum efficiencies for the generation of the photocurrents were determined by the electropolymerization of the CdS NPs and the Au/CdS NPs matrix on transparent ITO (Indium Tin Oxide) glasses. These measurements provide the absolute values of the charge separation efficiencies, independent with respect to the content of photoactive CdS NPs and the screening of the absorbance of the CdS NPs by the Au NPs. It was found that the quantum efficiency of light-to-electrical energy conversion corresponds to 2.1% for the oligoaniline CdS NPs system, and 8.6% for the oligoaniline Au/CdS NPs system.

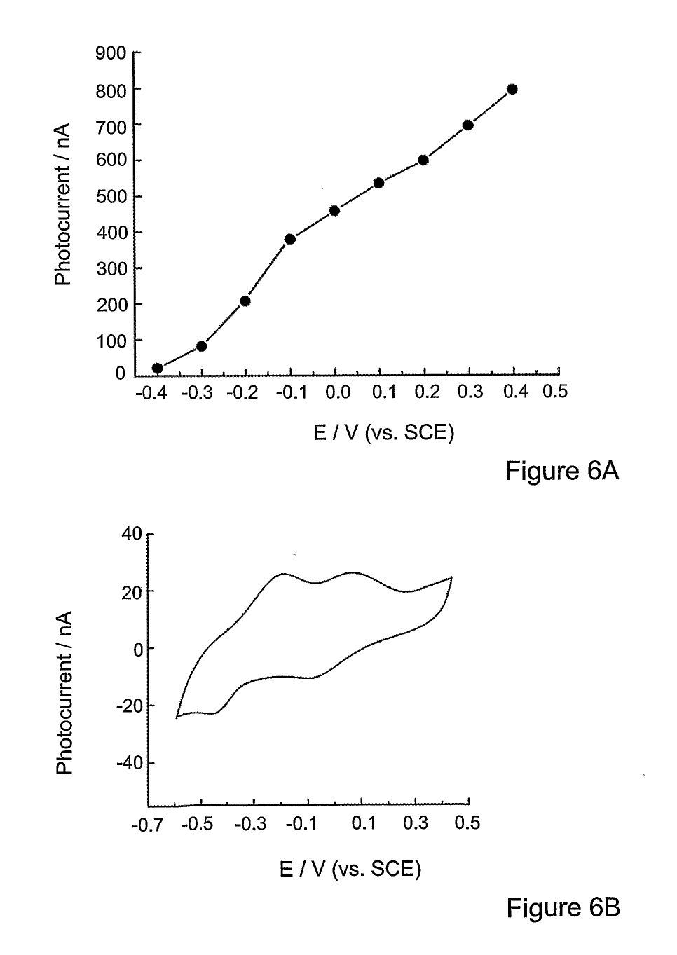

FIG. 6A demonstrates the effect of the potential applied on an electrode of an embodiment of the invention, on the resulting photocurrent of the Au/CdS NPs assembly on the Au electrode. Two major regions were shown in which the potential affects the photocurrent: (i) lowering the potential from +0.4 V to −0.1 V vs. SCE (Standard Calomel Electrode) results in a moderate decrease in the photocurrent intensity; (ii) a further decrease from −0.1 V to −0.4 V results in a sharp decrease in the photocurrents intensities.

This potential dependence can be explained by the redox-states of the oligoaniline connecting group (bridge), and the activity of the reduced unit as a charge carrier. The redox-potential of oligoaniline bridge is ca. 0.0 V vs. SCE (see FIG. 6B). Thus, in the first region the bridge exists in the quinoide oxidized state that acts as an electron acceptor. Accordingly, trapping the conduction-band electrons and their transfer by the Au NPs results in the flowing of the electrons to the electrode. At E<0 V, the quinoide connecting units become reduced. At their reduced state, the conjugated connecting groups lack electron acceptor properties, but they tunnel the electrons, through the Au NPs, to the electrode. As the connecting units do not trap the conduction band electrons by an energy gradient path, the charge separation becomes less efficient, and the intensities of the photocurrents decrease sharply. This may be attributed to the reduction of the driving force for transporting the conduction-band electrons to the electrode. At E=−0.4 V the photocurrent is almost zero since the electrode potential is as negative as the conduction-band potential, which eliminates the thermodynamic driving force for the generation of the photocurrent.

The electrode configurations revealed that the design of the oligoaniline Au/CdS NPs matrix provides effective charge transport and charge separation that leads to high value photocurrents. The highest values of photocurrents were, however, generated when the connecting units existed in their oxidized quinoide state, which acted as electron traps for the conduction-band electrons. Accordingly, in order to maintain the high photocurrents, the application of a positive potential on the electrode is required.

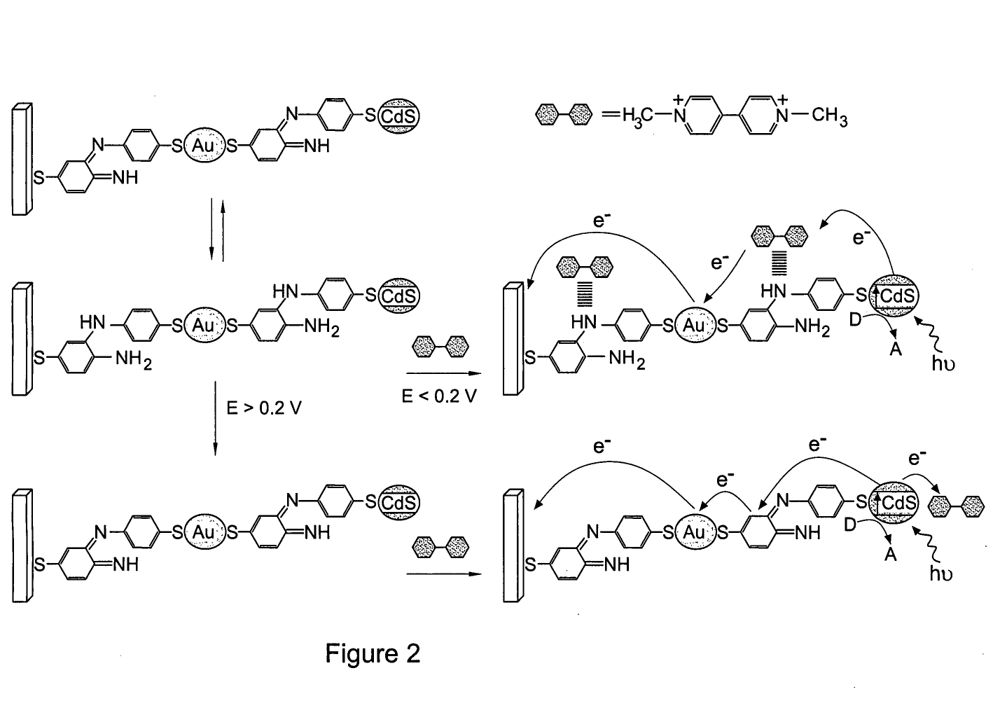

Furthermore, upon introduction of electron acceptor relay groups (or molecules) into the oligoaniline connected Au/CdS NPs matrices, particularly at zero or negative potentials applied on the electrode, the resulting photocurrents could be enhanced. Previous studies demonstrated that the covalent tethering of CdS NPs by a bipyridinium electron relay bridge improved the photocurrent yields by trapping the conduction-band electrons [32-35]. Additionally, it was reported that the use of oligoaniline connected Au NP arrays as a functional material for the sensitive electrochemical detection of the trinitrotoluene (TNT) explosive [41]. In the present invention, an electron acceptor such as for example N,N′-dimethyl-4,4′-bipyridinium (methyl viologen), MV²⁺, was added to the system in order to enhance the photocurrent by its association to the oligoaniline bridges by π donor-acceptor interactions as illustrated in FIG. 2.

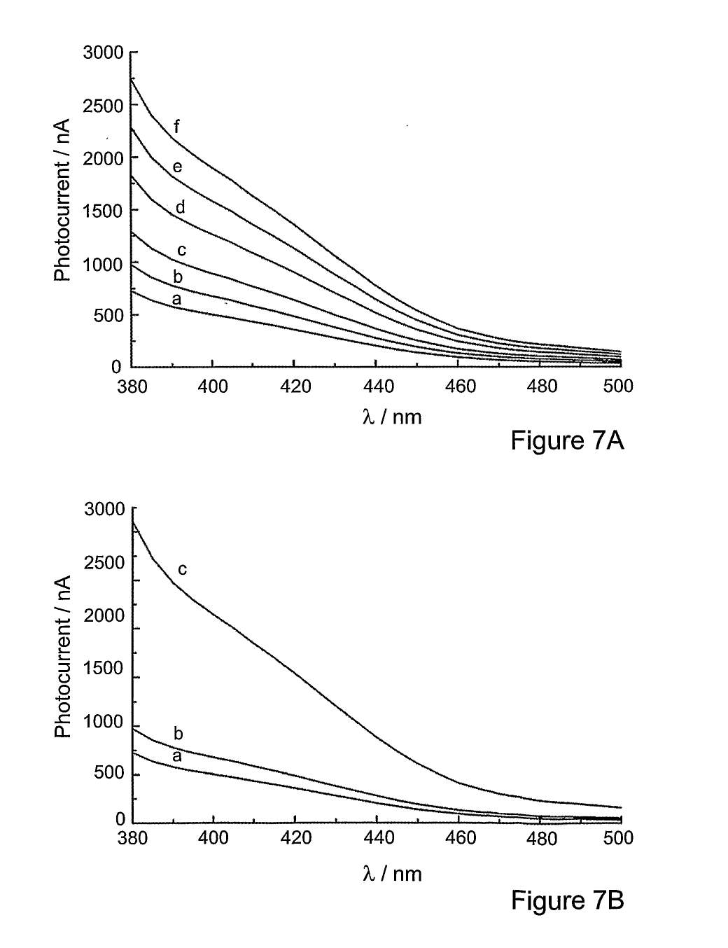

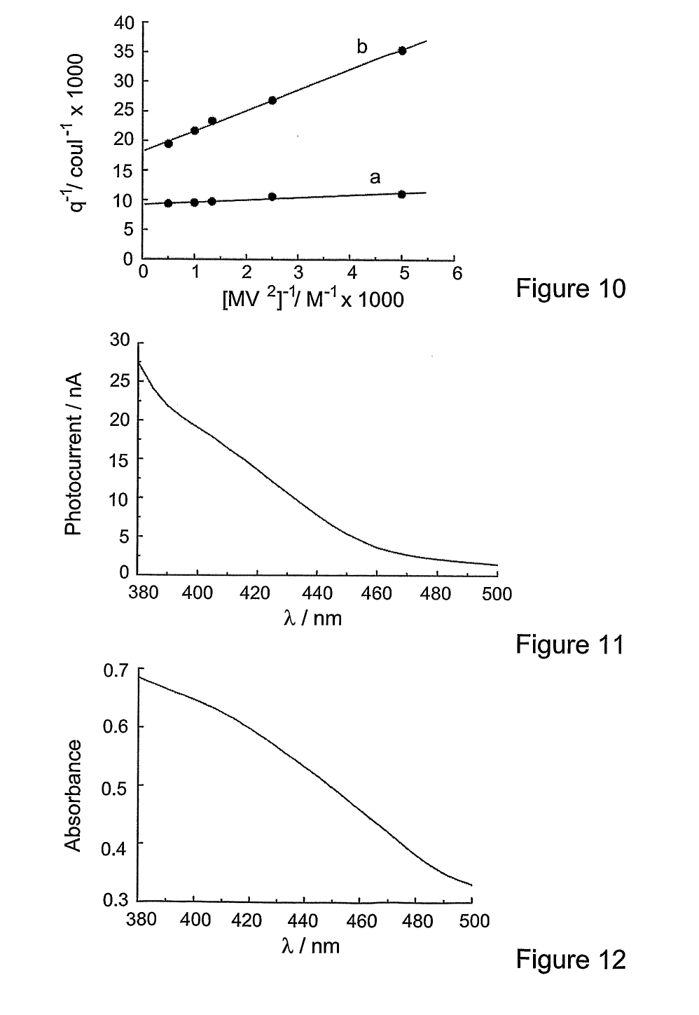

FIG. 7A shows the photocurrents generated by the oligoaniline Au/CdS NPs matrix in the presence of variable concentrations of MV²⁺, in comparison to the photocurrent generated in the absence of MV²⁺. As the concentration of MV²⁺ increases, the photocurrents are intensified. For example, at a MV²⁺ concentration of 2×10⁻⁴ M, the photocurrent at λ=400 nm increases from 520 nA to 750 nA, and by further increasing the concentration to 2×10⁻³ M the photocurrent is elevated to 2.3 μA, FIG. 7A, curve (f). The association of MV²⁺ to the oligoaniline connecting groups is described in Eq. (1) and the association constant, Kₐ, is expressed in Eq. (2) and its other form, Eq. (2a), where α is the number of π-donor oligoaniline sites in the system and θ is the fraction of sites that are complexed by MV²⁺ at any bulk concentration. Kₐ was determined independently by electrochemical means (see FIG. 10), and it corresponded to Kₐ=5270 M⁻¹.

$$\begin{matrix}{MV}^{2 +} + {Oligoaniline}_{α - θ} {⇌}^{{K}_{a}} {Oligoaniline}_{α} - {MV}^{2 +} . & Eq . ( 1 ) \\ {K}_{a} = \frac{θ}{( α - θ ) [ {MV}^{2 +} ]} & Eq ( 2 ) \\ \frac{1}{θ} = \frac{1}{α} + \frac{1}{α \cdot {K}_{a} [ {MV}^{2 +} ]} & Eq . ( 3 )\end{matrix}$$

As the bulk concentration of MV²⁺ was increased, the content of MV²⁺ in the matrix increased and thus, trapping of the conduction band electrons, and charge separation, of an electrode of the invention, were improved, resulting in higher photocurrent values. Thus, increasing the association constant of the electron acceptor groups to the oligoaniline connecting groups further enhances the resulting photocurrents.

Imprinting of molecular recognition sites in organic or inorganic polymer matrices (molecularly imprinted matrices (MIPs)) generates selective binding sites for molecular substrates [42-55]. The generation of the MIPs is achieved by complementary interactions between the imprinted substrate (or its structural analog) and the respective monomer unit. Electropolymerization of monomer units in the presence of a substrate yields polymers with molecular contours that selectively bind the imprinted substrate. An imprinted polymer matrix for methyl viologen, MV²⁺, was fabricated by the electropolymerization of phenol in the presence of MV²⁺, using oligophenol/MV²⁺ π donor-acceptor interactions as imprinting motif [56].

In accordance with an embodiment of the present invention, an electropolymerization process for the preparation of an electrode of the invention comprises thioaniline-Au NPs, thioaniline-CdS NPs, thioaniline layered conductive surface and MV²⁺. Since the electropolymerized thioaniline connecting groups may act as a π-donors, the electropolymerization yields an MV²⁺ imprinted matrix. The primary driving forces for the association of MV²⁺ to the matrix may be the π donor-acceptor interactions, which are synergistically stabilized by the imprinted molecular contours generated by the NPs.

FIG. 7B shows the photocurrent action spectrum of the MV²⁺-imprinted Au/CdS NPs electrode, curve (a), in comparison to the photocurrent action spectrum of the non-imprinted electrode, curve (b). For comparison, FIG. 7B, curve (c) shows the photocurrent action spectrum of the Au/CdS NPs electrode of an embodiment of the invention, in the absence of MV²⁺ is also presented. Whereas the photocurrent obtained by the electrode in the presence of MV²⁺, 0.2 mM, at λ=400 nm, is ca. 750 nA (as compared to 500 nA in the absence of MV²⁺), it significantly increases to 2.3 μA in the presence of the imprinted Au/CdS NPs matrix. This 3-fold increase in the photocurrent is attributed to the higher affinity of MV²⁺ to the imprinted NPs matrix on the electrode of the invention.

Without being bound by theory, it is assumed that as the content of MV²⁺ in the matrix becomes higher, it traps more effectively the conduction band electrons which results in a higher photocurrent. Indeed, complementary experiments examined the association constant of MV²⁺ to the imprinted oligoaniline-Au NPs matrix associated with the electrode (FIG. 10). The association constant of MV²⁺ to the imprinted Au/CdS NPs matrix corresponds to Ka=2.29×10⁴ M⁻¹, a value that was substantially higher than the association constant that was found for the non-imprinted NPs aggregated structure. The quantum yield for the photocurrent generated by the non-imprinted CdS/Au NPs matrix, in the presence of MV²⁺, 0.2 mM, and TEOA, 20 mM, corresponds to ca. 12%. Under similar conditions, the MV²⁺-imprinted CdS/Au NPs matrix reveals a substantially higher and impressive, quantum yield of photocurrent generation corresponding to ca. 34%.

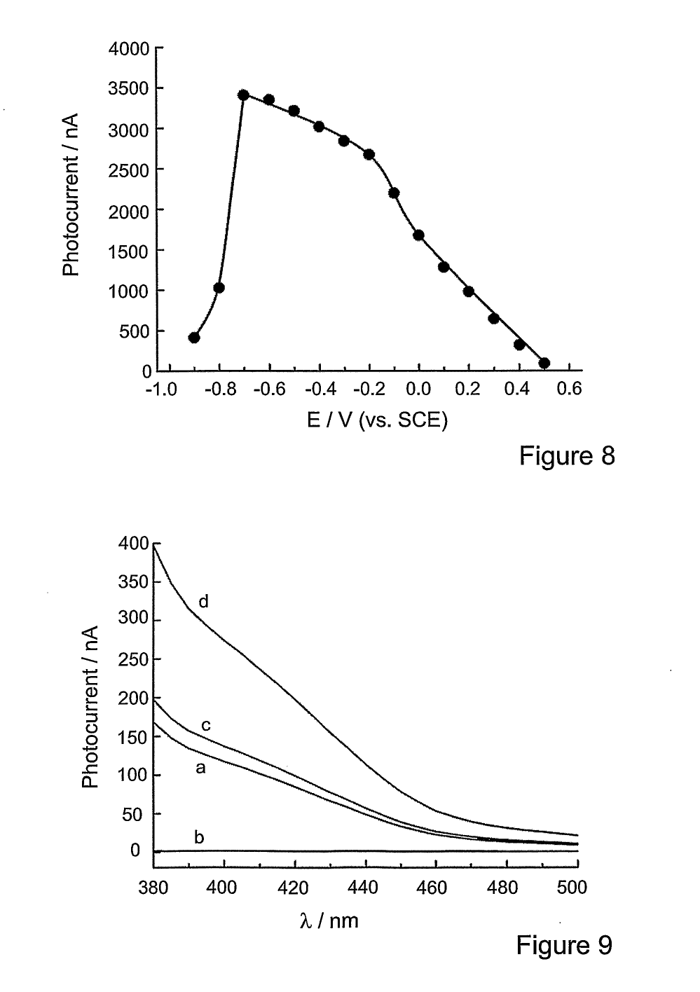

FIG. 8 demonstrates the effect of applied potentials on the photocurrent in the Au/CdS-NPs/MV²⁺ electrode of an embodiment of the invention. At potentials corresponding to E>0.2 V vs. SCE the photocurrent is lower than in the absence of any applied potential. A further decrease of the potential resulted in an increase in the photocurrent values up to the value of −0.7 V vs. where a sharp decline in the resulting photocurrent was observed. This photocurrent dependence on the applied potential was different from the observations regarding the Au/CdS NPs electrode in the absence of MV²⁺. At positive potentials, and in the absence of MV²⁺, the NPs-connected electrode of an embodiment of the invention revealed the highest photocurrents. This may be attributed to the existence of the connecting groups in the quinoide, electron acceptor, state, that trapped the conduction band electrons and effectively transferred them to the electrode. However, the addition of MV²⁺, at E>0.2 V, resulted in a reduction in the photocurrent. This may be attributed to the occurrence of a cathodic photocurrent path that competes with the aforementioned anodic photocurrent generation route, as illustrated in FIG. 2. Under these conditions, the MV²⁺ electron acceptor units lack connecting affinity to the quinoide oligoaniline bridging units, and are electrostatically-repelled from the surface.

As a result, the trapping of the conduction-band electrons by solution-solubilized MV²⁺ electron acceptor units, and the concomitant oxidation of triethanolamine (TEOA) proceed in the system. This process yielded a cathodic photocurrent that competed with the anodic photocurrent and resulted in lower net currents, in the oligoaniline oxidized potential state region.

As shown in FIG. 6A in the absence of MV²⁺, lowering the potential below E<0.1 V vs. SCE, resulted in a decrease in the photocurrents generated by the NPs-connected electrode. This was attributed to the reduction of the connecting groups to their π-donor oligoaniline states, which do not trap the conduction band electrons, and to the lowering of the thermodynamic driving force for electron transport as the electrode potential turns negative.

On the other hand, in the presence of MV²⁺, an increase the photocurrent value is observed up to −0.7 V vs. SCE. This is attributed to the favorable formation of π donor-acceptor complexes between the oligoaniline π-donor connecting groups and MV²⁺, and the subsequent action of the MV²⁺ acceptor units as efficient electron transfer traps. Furthermore, as the potential becomes negative, the electrostatic attraction of MV²⁺ to the matrix of an electrode of the invention is also favored, and the subsequent concentration of MV²⁺ in the composite further enhances the anodic photocurrent. For example, at −0.7 V vs. SCE, the MV²⁺ units become electrochemically reduced to the N,N′-dimethyl-4,4-bipyridinium radical cation state, MV⁺. This redox process depletes the electron acceptor units from the composite, resulting in the sharp decrease of the photocurrent. It should be noted that the formation of the cathodic photocurrent by the CdS NPs system, was further supported by probing the photocurrent generated by a CdS NPs layer linked to a Au electrode by 1,4-butane dithiol layer in the presence of MV²⁺/TEOA (see FIG. 11).

In all of the above exemplified electrode systems of the invention, triethanolamine (TEOA), was used as sacrificial electron donor. In order for the electrode of the invention to be utilized in a device such as for example a solar cell, a reversible non-sacrificial electron donor may be used.

FIG. 9, curve (a) shows the photocurrent action spectrum of the Au/CdS NPs electrode of an embodiment of the invention in the presence of I₃⁻ as a non-sacrificial electron donor. The photocurrent intensities decrease, when compared to the values observed with TEOA, but a reasonably high photocurrent intensity that corresponds to 125 nA at 400 nm was observed (quantum efficiency of ca. 2%).

For comparison, FIG. 9, curve (b) demonstrates that a system consisting of CdS NPs connected to the Au electrode by the oligoaniline groups without Au NPs, did not yield any detectable photocurrent (<3 nA) in the presence of I₃⁻. The performance of the Au/CdS NPs electrodes of an embodiment of the invention, in the presence of MV²⁺ and I₂ was further examined in the non-imprinted and imprinted configurations.

FIG. 9, curve (c) shows the photocurrent action spectrum of the MV²⁺-imprinted Au/CdS NPs electrode of an embodiment of the invention, upon irradiation of the electrode in the presence of MV²⁺, 0.2 mM, and I₃⁻, 10 mM. The resulting photocurrent at 400 nm is ca. 2-fold higher as compared to the analogous non-imprinted electrode (quantum efficiency of ca. 5%). The enhanced photocurrent was attributed, to the higher binding affinity of MV²⁺ to the oligoaniline π-donor connecting groups in the imprinted NPs matrix. The enhanced association of MV²⁺ to the photoactive array results in more efficient trapping of the conduction band electrons. The improved charge separation leads to the higher photocurrent value.

The invention will now be further illustrated in the following non-limiting examples:

### EXAMPLE 1

### Preparation of CdS Nanoparticles

An AOT/n-heptane water-in-oil microemulsion was prepared by the solubilization of 3.5 mL distilled water in 100 mL n-heptane in the presence of dioctyl sulfosuccinat sodium salt, AOT, as surfactant. The resulting mixture was separated into 60 mL and 40 mL sub-volumes. An aqueous solution of Cd(ClO₄)₂ (240 μL, 1.55M) and Na₂S (160 μL, 1.32M) was added to the 60 mL and 40 mL sub-volumes, respectively. The two sub-volumes were, then, mixed and stirred for 1 hour to yield the nanoparticles. For the preparation of thiol-capped CdS nanoparticles, a mixture consisting of an aqueous solution of 2-mercaptopropane sulfonic acid sodium salt (330 μL, 0.32 M) and p-aminothiophenol (66 μL, 0.32 M) was added to the resulting micellar solution and the mixture was stirred for 14 h under argon. Pyridine, 20 mL, was then added, and the resulting precipitate was washed and centrifuged with n-heptane, petrol butanol and methanol. An average particle size of 8.5±0.5 nm was estimated by TEM.

### EXAMPLE 2

### Preparation of Au Nanoparticles

Au nanoparticles functionalized with mercaptoethane sulfonic acid and p-aminothiophenol (Au-NPs) were prepared by mixing a 10 mL solution containing 197 mg HAuCl₄ in ethanol and a 5 mL solution containing 42 mg mercaptoethane sulfonate and 8 mg p-aminothiophenol in methanol. The two solutions were stirred in the presence of 2.5 mL glacial acetic acid in an ice bath for 1 hour. Subsequently, 7.5 mL aqueous solution of 1 M sodium borohydride, NaBH₄, was added dropwise, resulting in a dark colored solution associated with the resulting Au-NPs. The solution was stirred for 1 additional hour in an ice bath, and then for 14 hours at room temperature. The particles were successively washed and centrifuged (twice in each solvent) with methanol, ethanol and diethyl ether. An average particle size of 3.5±0.5 nm was estimated by TEM.

### EXAMPLE 3

### Fabricating Au Electrodes

Au slides (Au-coated glass slides from Nunc International, Rochester, USA) were cut to the size of 9×25 mm. The Au surfaces were treated with piranha solution (70% sulfuric acid and 30% hydrogen peroxide) for a period of 30 seconds (Piranha is a vigorous oxidant and should be used with extreme caution) and washed thoroughly with distilled water and ethanol. The resulting electrodes were then reacted with p-aminothiophenol, 50 mM in ethanol, for a period of 12 h. The oligoaniline-Au/CdS NPs matrices on Au surfaces were prepared by repetitive cyclic voltammetry scans in the presence of 0.1 M phosphate buffer pH=7.4, containing a mixture of the Au NPs and the CdS NPs at a fixed molar ratio. Control experiments for the generation of oligoaniline-CdS or oligoaniline-Au NPs (single component arrays) were carried out by repeating the above electropolymerization procedure but the presence of only CdS-modified or Au-modified NPs. MV²⁺-imprinted oligoaniline matrices comprising Au/CdS NPs were prepared by repetitive cyclic voltammetry scans in the presence of 0.1 M phosphate buffer pH=7.4, containing 10 mM MV²⁺ and a mixture of the Au NPs and CdS NPs at a fixed molar ratio. The potential range was −0.5 V to +0.5 V versus SCE and the scan rate was 100 mVs⁻¹. Extraction of the bound MV²⁺ was performed by shaking the electrodes in a phosphate buffer solution, pH=7.4, for 2 hours.

### EXAMPLE 4

### Chronoamperometry Determination of Association of MV²⁺ Electron Donor Groups in Oligoaniline-Crosslinked Au/CdS NPs Arrays

Chronoamperometry was used as the electrochemical method to determine the association constants of MV²⁺ to the non-imprinted, and imprinted, oligoaniline-crosslinked Au/CdS NPs arrays. In order to determine the MV²⁺ content associated with the oligoaniline π-donor Au/CdS NPs composite, or with the MV²⁺-imprinted oligoaniline π-donor Au/CdS NPs array, the fact that upon the application of a potential step to reduce the MV²⁺ units, the current transient includes a rapid mono-exponential decay corresponding to the reduction of the π-donor-confined MV²⁺ units, which is followed by a slow current decay corresponding to the reduction of diffusing MV²⁺ was considered. The rapid time-dependent current transient, I(t), which corresponds to the reduction of surface-confined MV²⁺ obeys Eq. (3), where kₑₜ is the electron-transfer rate coefficient, and q is the charge associated with the MV²⁺ linked to the surface.

I(t)=(kₑₜ·q)e^{-k}^{ₑₜ}^{·t} Eq. (3)

FIG. 10, curve (a), shows a coulometric analysis of MV²⁺ linked to the π-donor oligoaniline units that crosslink the Au/CdS NPs array, in the presence of variable bulk concentrations of MV²⁺. FIG. 10, curve (b) depicts the coulometric analysis of the MV²⁺ linked to the imprinted Au/CdS NPs array in the presence of variable bulk concentrations of MV²⁺.

Instrumentation

All electrochemical experiments were carried out using an Autolab electrochemical system (ECO Chemie, The Netherlands) driven by the GPES software. A saturated calomel electrode (SCE) and a carbon rod (d=5 mm) or platinum wire (d=0.5 mm) were used as the reference and counter electrodes, respectively. Photoelectrochemical experiments were performed using a home-built photoelectrochemical system that included a 300 W Xe lamp (Oriel, model 6258), a monochromator (Oriel, model 74000, 2 nm resolution), and a chopper (Oriel, model 76994). The electrical output from the cell was sampled by a lock-in amplifier (Stanford Research model SR 830 DSP). The shutter chopping frequency was controlled by a Stanford Research pulse/delay generator, model DE535. The photogenerated currents were measured between the modified Au working electrode and the carbon counter electrode. In experiments where the photocurrent was measured at different applied potentials, a three-electrode cell configuration (including a SCE reference electrodes) and an external potentiostat/galvanostat, EG&G Model 263, were used.

Quartz crystal microbalance (QCM) measurements were performed using a home-built instrument linked to a frequency analyzer (Fluke) using Au-quartz crystals (AT-cut 10 MHz). The geometrical area of the Au electrode was 0.2±0.05 cm². Prior to each measurement the modified QCM electrodes were dried under argon, and the crystal frequencies were determined under air.

1.-29. (canceled)

30. An electrode comprising a conductive surface connected to a matrix;
the matrix comprising a plurality of semiconductor nanoparticles and noble metal nanoparticles;
wherein substantially each nanoparticle of the plurality of nanoparticles is connected to another nanoparticle by at least one matrix connecting group capable of mediating electron transfer between nanoparticles of the matrix; and
at least a portion of the plurality of nanoparticles is connected to the conductive surface by at least one surface connecting group, capable of mediating electron transfer between the matrix and the conductive surface.

31. The electrode of claim 30, wherein each of the semiconductor nanoparticles of the plurality of semiconductor nanoparticles is selected from the group consisting of cadmium sulfide, cadmium selenide, cadmium telluride, indium selenide, and any combination thereof.

32. The electrode of claim 30, wherein each of the noble metal nanoparticles of the plurality of noble nanoparticles is selected from the group consisting of ruthenium, rhodium, palladium, silver, osmium, iridium, platinum, gold, and any combination thereof.

33. The electrode of claim 30, wherein the ratio of semiconductor nanoparticles to noble metal nanoparticles in the matrix is between about 0.1 to about 10.0.

34. The electrode of claim 30, wherein transfer of electrons mediated by a matrix connecting group and/or surface connecting group is achieved through charge-hopping or electron tunneling.

35. The electrode of claim 30, wherein the matrix connecting group is an electropolymerized oligomer.

36. The electrode of claim 35, wherein the electropolymerized oligomer comprises at least two anchoring groups which may be the same or different and are each independently chemically associated with at least one nanoparticle of the matrix.

37. The electrode of claim 30, wherein the matrix connecting group is a group of the formula (I):
Z₁-L₁-Z₂ (I)
wherein each of the Z₁ and Z₂, which may be the same or different, is a bond or a moiety independently chemically associated with at least one nanoparticle; and
L₁ is a linker group comprising at least one electropolymerized monomer or oligomer thereof.

38. The electrode of claim 30, wherein the surface connecting group is an electropolymerized oligomer.

39. The electrode of claim 30, wherein the surface connecting group is a group of the formula (II):
Z₃-L₂-Z₄ (II)
wherein each of the Z₃ and Z₄, which may be the same or different, is a bond or a moiety that are each independently chemically associated with at least one nanoparticle or conductive surface; and
L₂ is a linker group comprising at least one electropolymerized monomer or oligomer thereof.

40. The electrode of claim 30, further comprising at least one electron acceptor group having a redox potential that is more positive than the conductive band of the semiconductor nanoparticles.

41. The electrode of claim 40, wherein the electron acceptor group is selected from the group consisting of N,N′-dimethyl-4,4′-bipyridinium, quinone, ferric cyanide, molybdenum cyanide and any combination thereof.

42. A photovoltaic cell comprising the electrode of claim 30.

43. A device comprising a photo-sensitive electrode, the electrode being an electrode according to claim 30.

44. A process of preparing an electrode, comprising:
forming a layer on a conductive surface comprising at least one electropolymerizable group having the general formula (V):
Z₃-L₂ (V)
wherein Z₃ is a bond or a moiety that is chemically associated with the conductive surface; and L₂ is a linker group comprising at least one electropolymerized monomer or oligomer thereof;
contacting the layered conductive surface with a plurality of semiconductor nanoparticles and noble metal nanoparticles, each nanoparticles being independently chemically associated with at least one electropolymerizable group having the general formula (VI):
Z₁-L₁ (VI)
wherein Z₁ is a bond or a moiety that is chemically associated with the nanoparticle; and L₁ is a linker group comprising at least one electropolymerized monomer or oligomer thereof; and
electropolymerizing the plurality of nanoparticles and the layered surface to form an electrode comprising a conductive surface connected to a matrix;
wherein the matrix comprises a plurality of semiconductor nanoparticles and noble metal nanoparticles; and
wherein substantially each nanoparticle of the plurality of nanoparticles is connected to another nanoparticle of the plurality of nanoparticles by at least one electropolymerized group; and at least a portion of the plurality of nanoparticles of the matrix is each connected to the conductive surface by at least one electropolymerized group.

45. The process of claim 44, wherein each of L₁ and L₂ independently comprises one or more optionally substituted aromatic or heteroaromatic moieties.

46. The process of claim 44, wherein L₁ and L₂ are each independently an electropolymerized monomer selected from the group consisting of thioaniline, thiophenol, amino-thiophenol, thiopyrrol, and any combination thereof.

47. The process of claim 44, wherein the electropolymerizing step is performed in the presence of at least one electron acceptor group having a redox potential that is more positive than the conductive band of the semiconductor nanoparticles.

48. The process of claim 44, wherein at least one electron acceptor molecule having a redox potential that is more positive than the conductive band of the semiconductor nanoparticles is added following electropolymerization step.

49. The process of claim 44, wherein the electron acceptor molecule is selected from the group consisting of N,N′-dimethyl-4,4′-bipyridinium, quinone, ferric cyanide, molybdenum cyanide, and any combination thereof.
